(19) United States
(12) Patent Application Publication
(10) Pub. No.: US 2024/0222516 A1
(43) Pub. Date: Jul. 4, 2024

(54) THIN FILM TRANSISTOR SUBSTRATE AND DISPLAY APPARATUS COMPRISING THE SAME

(71) Applicant: LG DISPLAY CO., LTD., Seoul (KR)

(72) Inventors: Youngjin YI, Paju-si (KR); WonSang RYU, Paju-si (KR); SungSoo SHIN, Paju-si (KR)

(73) Assignee: LG DISPLAY CO., LTD., Seoul (KR)

(21) Appl. No.: 18/473,976

(22) Filed: Sep. 25, 2023

(30) Foreign Application Priority Data
Dec. 30, 2022 (KR) 10-2022-0190635

(51) Int. Cl. H01L 29/786; G09G 3/3266; H01L 29/423; H10K 59/121

(52) U.S. Cl. CPC H01L 29/7869; G09G 3/3266; H01L 29/42384; H01L 29/78633; H10K 59/1213; G09G 2310/0286

(57) ABSTRACT

A thin film transistor substrate can include a first thin film transistor disposed on a substrate, the first thin film transistor including a first source electrode, a first drain electrode, a first active layer and a first gate electrode, in which the first gate electrode is disposed on the first active layer and includes a transparent conductive oxide semiconductor material. Also, the first gate electrode can be transparent and can allow light to be irradiated onto the first active layer to release a buildup of charges from accumulating within the first active layer while the first thin film transistor is in operation in order to maintain a more constant threshold voltage.

### CROSS-REFERENCE TO RELATED APPLICATIONS

This application claims priority under 35 U.S.C. § 119(a) to Korean Patent Application No. 10-2022-0190635 filed in the Republic of Korea on Dec. 30, 2022, the entirety of which is hereby incorporated by reference as if fully set forth herein.

### BACKGROUND

### Technical Field

The present disclosure relates to a thin film transistor substrate and a display apparatus comprising the same.

### Description of the Related Art

Since a thin film transistor can be manufactured on a glass substrate or a plastic substrate, it is widely used as a switching element or a driving element of a display apparatus such as a liquid crystal display apparatus or an organic light emitting device.

The display apparatus includes a plurality of pixels and a driving unit for driving the plurality of pixels, and the plurality of thin film transistors are provided in the plurality of pixels and the driving unit. The plurality of thin film transistors can have various characteristics according to an environment and a connection relationship in which the device is driven. Meanwhile, the buffer unit provided in the gate driver includes the plurality of thin film transistors, such as a pull-up transistor Tu and a pull-down transistor Td, and the thin film transistor provided in the buffer unit is applied with a higher positive bias than other thin film transistors. Accordingly, the reliability of the plurality of thin film transistors provided in the buffer unit is likely to deteriorate due to a relatively high positive bias. For example, charges can build up in the active layer of the thin film transistors that operate under high positive bias conditions, and over time this can cause the threshold voltage Vth of the thin film transistor to drift in an undesirable manner.

Furthermore, among the plurality of thin film transistors provided in the plurality of pixel areas, the switching transistor for light emission control is similarly applied with a high positive bias. Therefore, the reliability of the switching transistor for light emission control is also likely to deteriorate due to a relatively high positive bias.

In order to optimize the characteristics of thin film transistors provided in the display apparatus according to the characteristics of the device, different types of thin film transistors suitable for device characteristics can be implemented by having active layers on different layers. However, in this situation, a gate insulating layer is additionally provided for insulation and protection between the upper thin film transistor and the lower thin film transistor, which can increase the thickness of the upper thin film transistor or lower thin film transistor, reducing on current characteristics or making S-factor adjustment difficult.

### SUMMARY OF THE DISCLOSURE

The present disclosure has been made in view of the problems, and it is an object of the present disclosure to provide a thin film transistor substrate and display apparatus that maintains reliability even when used for a long time by including a conductive transparent oxide semiconductor material in a gate electrode of the thin film transistor in an environment where high constant voltage is continuously applied.

Also, it is an object of the present disclosure to provide thin film transistor substrates and display apparatus that do not require additional insulation layers between the upper thin film transistor and the lower thin film transistor by the gate electrode of the lower thin film transistor including a transparent oxide semiconductor material.

Also, it is an object of the present disclosure to provide thin film transistor substrates and display apparatus that can easily adjust the S-factor while some thin film transistors increase on-current characteristics according to device characteristics because there is no need to have an additional insulation layer between the upper and lower thin film transistors.

In accordance with an aspect of the present disclosure, the above and other objects can be accomplished by the provision of a thin film transistor substrate and display apparatus including a substrate; and a first thin film transistor disposed on the substrate, in which the first thin film transistor includes a first source electrode, a first drain electrode, a first active layer and a first gate electrode, and the first gate electrode is disposed on the first active layer, includes transparent conductive oxide semiconductor material.

In accordance with an aspect of the present disclosure, the above and other objects can be accomplished by the provision of a thin film transistor substrate and display apparatus including a second thin film transistor with an additional light shielding layer in the first thin film transistor, and the second thin film transistor provides a thin film transistor substrate in which light cannot pass through the second gate electrode and cannot reach the second active layer.

In accordance with an aspect of the present disclosure, the above and other objects can be accomplished by the provision of a thin film transistor substrate and display apparatus including a third thin film transistor on a different layer from the first thin film transistor, and the third thin film transistor includes a third source electrode, a third drain electrode, a third active layer, and a third gate electrode, and the first gate electrode of the first thin film transistor and the third active layer of the third thin film transistor are disposed on the same layer.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a schematic diagram of a display apparatus according to an embodiment of the present disclosure.

FIG. 2 is a schematic diagram of a shift register according to an embodiment of the present disclosure.

FIG. 3 is a circuit diagram of a shift register according to an embodiment of the present disclosure.

FIG. 4A is a plan view of a first thin film transistor and a second thin film transistor according to an embodiment of the present disclosure.

FIG. 4B is a cross-sectional view of a buffer unit according to an embodiment of the present disclosure. In this situation, FIG. 4B corresponds to the cross section I-I′ of FIG. 4A.

FIG. 4C is a cross-sectional view of a node controller according to an embodiment of the present disclosure. In this situation, FIG. 4C corresponds to the cross section II-II′ of FIG. 4A.

FIG. 5 is a graph of reliability of the first thin film transistor in a positive bias temperature stress (PBTS) environment and reliability in a positive bias temperature illumination stress (PBTIS) environment according to an embodiment of the present disclosure.

FIG. 6 is a plan view of a thin film transistor substrate according to another embodiment of the present disclosure.

FIG. 7A is a cross-sectional view of a second thin film transistor according to another embodiment of the present disclosure. In this situation, FIG. 7A corresponds to a cross section III-III′ of FIG. 6.

FIG. 7B is a cross-sectional view of a second thin film transistor according to another embodiment of the present disclosure. In this situation, FIG. 7B corresponds to a cross section III-III′ of FIG. 6.

FIG. 8 is a circuit diagram of one pixel provided in a display area according to another embodiment of the present disclosure.

FIG. 9 is a circuit diagram of one pixel provided in a display area according to another embodiment of the present disclosure.

FIG. 10 is a cross-sectional view of a thin film transistor substrate according to another embodiment of the present disclosure.

FIG. 11A is a cross-sectional view of a thin film transistor substrate according to another embodiment of the present disclosure.

FIG. 11B is a cross-sectional view of a thin film transistor substrate according to another embodiment of the present disclosure.

FIG. 12 is a cross-sectional view of a display apparatus including a thin film transistor substrate according to an embodiment of the present disclosure.

### DETAILED DESCRIPTION OF THE EMBODIMENTS

Advantages and features of the present disclosure, and implementation methods thereof will be clarified through the following embodiments, described with reference to the accompanying drawings. The present disclosure can, however, be embodied in different forms and should not be construed as being limited to the embodiments set forth herein. Rather, these embodiments are provided so that this disclosure will be thorough and complete, and will fully convey the scope of the present disclosure to those skilled in the art. Further, the present disclosure is only defined by the scope of the claims.

The shapes, sizes, ratios, angles, and numbers disclosed in the drawings for describing embodiments of the present disclosure are merely examples, and thus the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted.

In the situation in which “comprise,” “have,” and “include” described in the present specification are used, another part can also be present unless “only” is used. The terms in a singular form can include plural forms unless noted to the contrary.

In construing an element, the element is construed as including an error region although there is no explicit description thereof.

In describing a positional relationship, for example, when the positional order is described as “on,” “above,” “below,” “beneath”, and “next,” the situation of no contact therebetween can be included, unless “just” or “direct” is used.

If it is mentioned that a first element is positioned “on” a second element, it does not mean that the first element is essentially positioned above the second element in the figure. The upper part and the lower part of an object concerned can be changed depending on the orientation of the object. Consequently, the situation in which a first element is positioned “on” a second element includes the situation in which the first element is positioned “below” the second element as well as the situation in which the first element is positioned “above” the second element in the figure or in an actual configuration.

In describing a temporal relationship, for example, when the temporal order is described as “after,” “subsequent,” “next,” and “before,” a situation which is not continuous can be included, unless “just” or “direct” is used.

It will be understood that, although the terms “first,” “second,” etc. can be used herein to describe various elements, these elements should not be limited by these terms. These terms are only used to distinguish one element from another. For example, a first element could be termed a second element, and, similarly, a second element could be termed a first element.

It should be understood that the term “at least one” includes all combinations related with any one item. For example, “at least one among a first element, a second element and a third element” can include all combinations of two or more elements selected from the first, second and third elements as well as each element of the first, second and third elements.

Features of various embodiments of the present disclosure can be partially or overall coupled to or combined with each other, and can be variously inter-operated with each other and driven technically. The embodiments of the present disclosure can be carried out independently from each other, or can be carried out together in a co-dependent relationship.

In the drawings, the same or similar elements are denoted by the same reference numerals even though they are depicted in different drawings.

In the embodiments of the present disclosure, a source electrode and a drain electrode are distinguished from each other, for convenience of explanation. However, the source electrode and the drain electrode are used interchangeably. Thus, the source electrode can be the drain electrode, and the drain electrode can be the source electrode. Also, the source electrode in any one embodiment of the present disclosure can be the drain electrode in another embodiment of the present disclosure, and the drain electrode in any one embodiment of the present disclosure can be the source electrode in another embodiment of the present disclosure.

In one or more embodiments of the present disclosure, for convenience of explanation, a source region is distinguished from a source electrode, and a drain region is distinguished from a drain electrode. However, embodiments of the present disclosure are not limited to this structure. For example, a source region can be a source electrode, and a drain region can be a drain electrode. Also, a source region can be a drain electrode, and a drain region can be a source electrode.

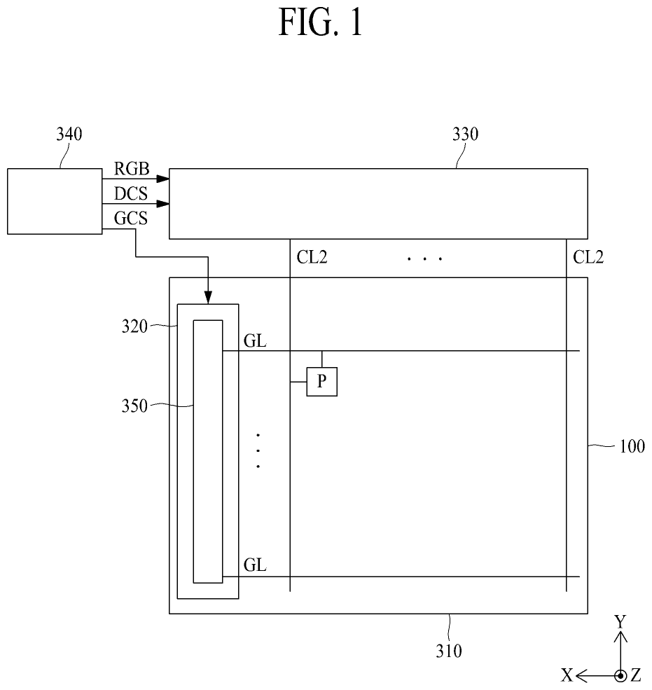

FIG. 1 is a schematic diagram of a display apparatus according to an embodiment of the present disclosure.

As shown in FIG. 1, the display apparatus according to an embodiment of the present disclosure can include a display panel 310, a gate driver 320, a data driver 330, and a controller 340.

The display panel 310 includes gate lines GLs and data lines DLs, and pixels P are disposed in respective crossing areas of the gate lines GLs and data lines DLs. An image is displayed by driving the pixel P. The gate lines GLs, the data lines DLs, and the pixels P can be disposed on the substrate 100.

The controller 340 controls the gate driver 320 and the data driver 330. The controller 340 outputs a gate control signal GCS for controlling the gate driver 320 and a data control signal DCS for controlling the data driver 330 by using a signal supplied from an external system. Also, the controller 340 samples input video data input from the external system and rearranges the sampled input video data, and supplies the rearranged digital video data RGB to the data driver 330.

The gate control signal GCS includes a gate start pulse GSP, a gate shift clock GSC, a gate output enable signal GOE, a start signal Vst, and a gate clock GCLK. Further, control signals for controlling a shift register can be included in the gate control signal GCS.

The data control signal DCS includes a source start pulse SSP, a source shift clock signal SSC, a source output enable signal SOE, and a polarity control signal POL.

The data driver 330 supplies a data voltage to the data lines DL of the display panel 310. Specifically, the data driver 330 converts the video data RGB inputted from the controller 340 into an analog data voltage and supplies the data voltage to the data lines DL.

The gate driver 320 can be mounted on the display panel 310. As described above, a structure in which the gate driver 320 is directly mounted on the display panel 310 is referred to as a gate in panel (GIP) structure. Specifically, in the gate-in-panel (GIP) structure, the gate driver 320 can be disposed on the substrate 100.

The gate driver 320 can include a shift register 350.

The shift register 350 sequentially supplies gate pulses to the gate lines GL during one frame by the use of start signal and gate clock transmitted from the controller 340. Herein, the one frame refers to a period in which one image is outputted through the display panel 310. The gate pulse has a turn-on voltage capable of turning on a switching device (thin film transistor) disposed in the pixel P.

Also, during the remaining period of one frame, in which the gate pulse is not supplied, the shift register 350 supplies a gate-off signal capable of turning off the switching device to the gate line GL. Hereinafter, the gate pulse and the gate-off signal are totally referred to as a scan signal GS.

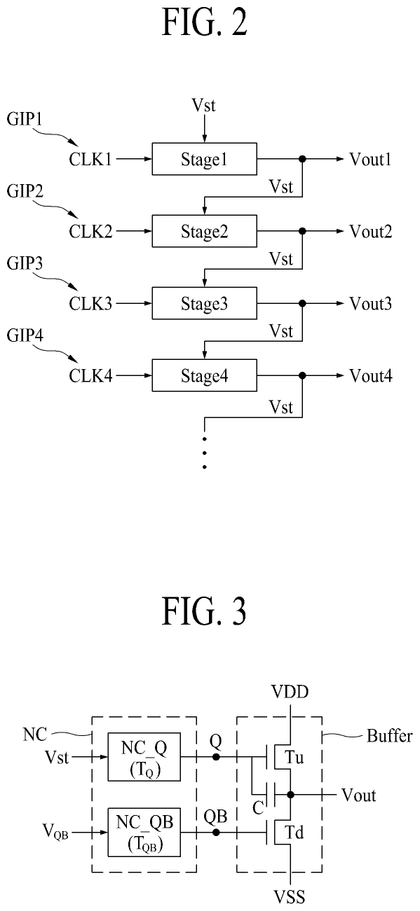

FIG. 2 is a schematic diagram of a shift register according to an embodiment of the present disclosure.

As shown in FIG. 2, each of the plurality of GIP circuits GIP1, GIP2, GIP3 and GIP4 outputs the gate signal Vout1, Vout2, Vout3 and Vout4 for one frame and supplies it to the gate wiring.

Specifically, in the first stage (Stage1) of the first GIP circuit GIP1 is initiated by a separate start signal VST, outputs the first gate signal Vout1 using the first clock signal CLK1 and supplies it to the first gate wiring.

the second to fourth stage Stage 2-Stage 4 of each of the second to fourth GIP circuits GIP2, GIP3 and GIP4 is initiated by the signal Vst, outputs the second to fourth gate signals Vout2, Vout3 and Vout4 using the second to fourth clock signal CLK2, CLK3 and CLK4 and supplies to the second to fourth gate wiring.

On the other hand, when the last gate signal Vout is output at the stage of the last GIP circuit where one frame ends, the stage of the last GIP circuit is initialized by receiving the reset signal Vreset, and then the first gate signal Vout1 is output at the first stage (Stage 1) of the first GIP circuit GIP1 where the next frame starts and above described is repeated.

FIG. 3 is a circuit diagram of a shift register according to an embodiment of the present disclosure. In this situation, each of the plurality of GIP circuits GIP1 to GIP4 illustrated in FIG. 2 can include, but is not necessarily limited to, the circuit as illustrated in FIG. 3.

As shown in FIG. 3, the GIP circuit includes a pull-up node Q, a pull-down node QB, a node controller NC, and a buffer unit Buffer.

The buffer unit Buffer is connected to an output terminal and includes a pull-up transistor Tu, a pull-down transistor Td, and a capacitor C.

The pull-up transistor Tu is turned on to output the gate-on signal when the pull-up node Q is charged with a gate high voltage.

The pull-down transistor Td is turned on to output the gate-off signal when the pull-down node QB is charged with a gate low voltage.

The capacitor C serves to maintain the gate high voltage supplied to the pull-up transistor Tu for one frame, and is provided between the gate terminal and the source terminal of the pull-up transistor Tu.

The node controller NC controls charging and discharging between the pull-up node Q and the pull-down node QB. The node controller NC can include a pull-up node controller NC_Q for controlling charging and discharging of the pull-up node Q and a pull-down node controller NC_QB for controlling charging and discharging of the pull-down node QB. The pull-up node controller NC_Q includes at least one transistor TQ for controlling the pull-up node Q, and the pull-down node controller NC_QB includes at least one transistor TQB for controlling the pull-down node QB.

The output of the gate signal Vout can be stably controlled by the node controller NC. Specifically, the node controller NC discharges the pull-down node QB to a gate low voltage when the pull-up node Q is charged with a gate high voltage, and discharges the pull-up node Q to a gate low voltage when the pull-down node QB is charged with a gate high voltage.

Therefore, when the start signal Vst is applied, the pull-up node Q is charged with a gate high voltage and the pull-down node QB is discharged with a gate low voltage by the operation of the plurality of transistors TQ and TQB provided in the node controller NC, thereby outputting the high source voltage VDD as the gate signal Vout. In addition, when a discharge signal VQB is applied, the pull-up node Q is charged with a gate low voltage and the pull-down node QB is charged with a gate high voltage by the operation of the plurality of transistors TQ and TQB provided in the node controller NC to output a low power voltage VSS as a gate signal Vout.

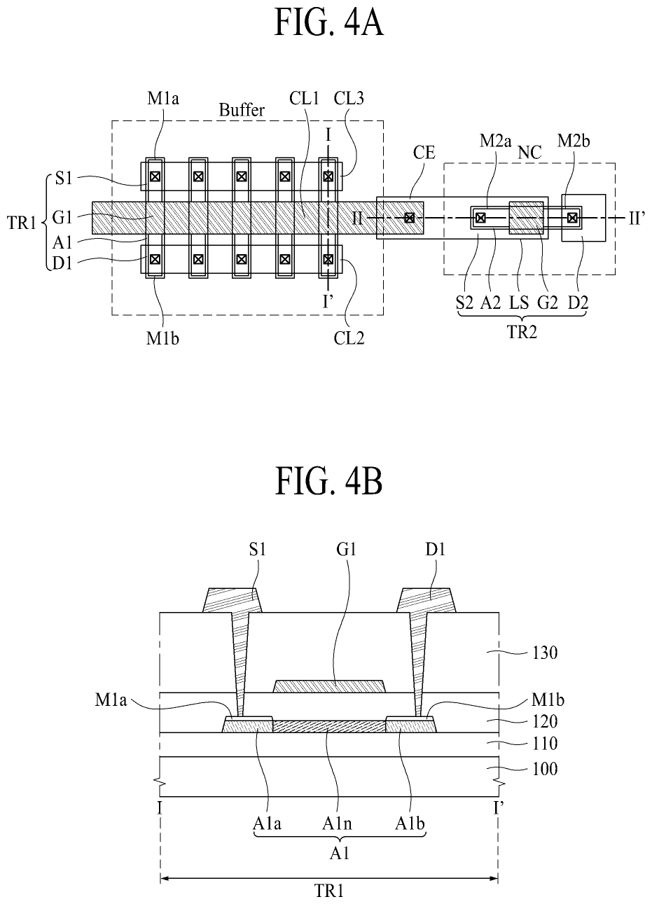

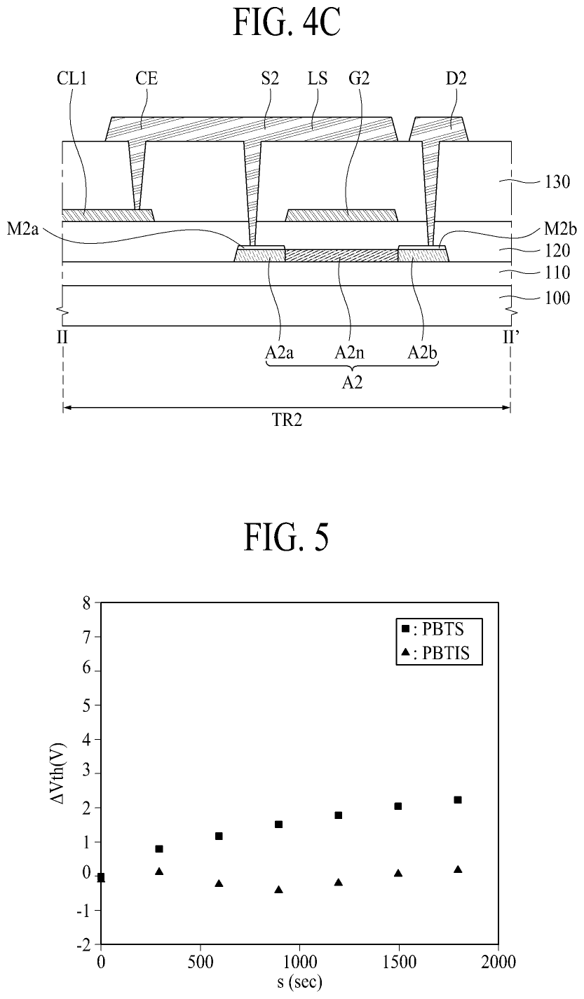

FIG. 4A is a plan view of a first thin film transistor and a second thin film transistor according to an embodiment of the present disclosure.

The thin film transistor substrate according to an embodiment of the present disclosure can include a buffer unit Buffer, a node controller NC, and a connection electrode CE.

The buffer unit Buffer includes a first conductive line CL1, a second conductive line CL2, a third conductive line CL3, and a plurality of first thin film transistors TR1 connected in parallel.

The first conductive line CL1, the second conductive line CL2, and the third conductive line CL3 are extended in a first direction, for example, the horizontal direction. The second conductive line CL2 is disposed on one side, for example, a lower side of the first conductive line CL1 and the third conductive line CL3 is disposed on another side, for example, an upper side of the first conductive line CL1.

The first conductive line CL1 receives a gate high voltage or a gate low voltage from the node controller NC to control the operation of multiple thin film transistors connected in parallel.

The first conductive line CL1 includes an oxide semiconductor. Specifically, the first conductive line CL1 includes a transparent conductive oxide semiconductor.

The second conductive line CL2 is connected to a wiring providing a high power voltage VDD so that a high power voltage VDD can be applied to the pull-up transistor Tu, or a wiring providing a low power voltage VSS can be applied to the pull-down transistor Td.

The third conductive line CL3 can be electrically connected to the output terminal of the gate signal Vout so that the high power voltage VDD applied from the second conductive line CL2 can be output to the gate signal Vout, or the low power voltage VSS applied from the second conductive line CL2 can be output to the gate Vout signal.

Each of the plurality of first thin film transistors TR1 connected in parallel includes a first gate electrode G1 formed as a portion of the first conductive line CL1, a first source electrode S1 formed as a portion of the third conductive line CL3, a first drain electrode D1 formed as a portion of the second conductive line CL2, a first active layer A1, a first conductive material layer M1a and a second conductive material layer M1b.

Since the first gate electrode G1 is a portion of the first conductive line CL1, the first gate electrode G1 is made of the same material as the first conductive line CL1. That is, the first gate electrode G1 includes an oxide semiconductor, especially a transparent conductive oxide semiconductor, and accordingly, the thin film transistor substrate according to an embodiment of present disclosure can have improved reliability in a PBTIS (Positive Bias Temperature Illumination Stress) environment, which will be described later.

The plurality of first active layers A1 extend in a second direction, for example, in a vertical direction, crossing the first conductive line CL1. One end, for example, an upper end of each of the plurality of first active layers A1, overlaps with the third conductive line CL3, and another end, for example, a lower end of each of the plurality of first active layers A1, overlaps with the second conductive line CL2.

The area of the third conductive line CL3 overlapping with the plurality of first active layers A1 becomes the first source electrode S1, and the area of the second conductive line CL2 overlapping with the plurality of first active layers A1 becomes the first drain electrode D1.

The plurality of first thin film transistors TR1 can include a pull-up transistor Tu or a pull-down transistor Td.

The node controller NC includes a second thin film transistor TR2.

The second thin film transistor TR2 includes a second gate electrode G2, a second source electrode S2, a second drain electrode D2, a second active layer A2, a first conductive material layer M2a, a second conductive material layer M2b, and a light shielding layer LS.

The second source electrode S2 is provided on one side, for example, the left side of the second active layer A2, the second drain electrode D2 is provided on another side, for example, the right side of the second active layer A2, the second gate electrode G2 is provided to overlap with the second active layer A2, and the light shielding layer LS is provided to overlap with the second gate electrode G2. For example, the second gate electrode G2 is between the light shielding layer LS and the second active layer A2.

The second gate electrode G2 is made of the same material as the first gate electrode G1 provided in the buffer unit Buffer. Accordingly, the second gate electrode G2 includes an oxide semiconductor, in particular, a transparent conductive oxide semiconductor.

The connection electrode CE extends in the first direction, for example, in the horizontal direction, to connect the buffer unit Buffer and the node controller NC. For example, the connection electrode CE can connect the first conductive line CL1 of the buffer unit Buffer with the second source electrode S2 of the node controller NC. Also, the first conductive line CL1 and the second gate electrode G2 can be made of a same material and disposed on a same layer (e.g., gate insulating layer 120).

The connection electrode CE can be connected to the first conductive line CL1 of the buffer unit Buffer through a contact hole. In addition, the connection electrode CE can be integrally formed with the second source electrode S2 of the node controller NC, but is not necessarily limited thereto.

The connection electrode CE can extend over the second gate electrode G2 to overlap with the second gate electrode G2, and thus the connection electrode CE can be integrally formed with the light shielding layer LS. However, it is not necessarily limited thereto, the connection electrode CE does not have to overlap with the second gate electrode G2, and a separate light shielding layer LS can be provided in the second thin film transistor TR2 that overlaps with the second gate electrode G2.

FIG. 4B is a cross-sectional view of a buffer unit according to an embodiment of the present disclosure. In this situation, FIG. 4B corresponds to the cross section I-I′ of FIG. 4A.

As shown in FIG. 4B, the buffer unit Buffer includes a substrate 100, a buffer layer 110, a first active layer A1, a first conductive material layer M1a, a second conductive material layer M1b, a gate insulating layer 120, a first gate electrode G1, an interlayer insulating layer 130, a first source electrode S1, and a first drain electrode D1. In this situation, the first active layer A1, the first gate electrode G1, the first source electrode S1, and the first drain electrode D1 form the first thin film transistor TR1.

The substrate 100 can be made of glass or plastic. In particular, the substrate 100 can be made of transparent plastic having flexible characteristics, for example, polyimide. When polyimide is used as the substrate 100, heat-resistant polyimide that can withstand high temperatures can be used considering that a high-temperature deposition process is performed on the substrate 100.

The buffer layer 110 is formed on the substrate 100. The buffer layer 110 can protect the first active layer A1 by blocking air and moisture. The buffer layer 110 can be made of an inorganic insulating material, such as silicon oxide, silicon nitride, or metal oxide, but is not limited thereto and can be made of an organic insulating material. The buffer layer 110 can be formed of a single layer or can be formed of a plurality of layers.

The first active layer A1 is formed on the buffer layer 110.

The first active layer A1 can include an oxide semiconductor material known to have high mobility characteristics. The oxide semiconductor material can include, for example, at least one of an IGZO-based oxide semiconductor material, an IZO-based oxide semiconductor material, an IGZTO-based oxide semiconductor material, an ITZO-based oxide semiconductor material, a FIZO-based oxide semiconductor material, a ZnO-based oxide semiconductor material, and a ZnON-based oxide semiconductor material, but embodiments are not limited thereto. When the first active layer A1 includes indium In and gallium Ga, the concentration (at %) of indium In can be set to be higher than the concentration (at %) of gallium Ga based on the number of atoms[In concentration>Ga concentration].

The first active layer A1 includes a channel part A1n, a first connection part Ala, and a second connection part Alb.

The first connection part A1a can be connected to one side of the channel part A1n, and the second connection part A1b can be connected to another side of the channel part A1n. The first connection part A1a and the second connection part A1b may not overlap with the first gate electrode G1. The first connection part A1a and the second connection part A1b have excellent conductivity compared to the channel part A1n, and each can serve as a wiring or source/drain electrode.

The conductive material layers M1a and M1b include a first conductive material layer M1a provided on an upper surface of the first connection part A1a and a second conductive material layer M1b provided on an upper surface of the second connection part A1b.

The upper surface of the first connection part A1a is in contact with the lower surface of the first conductive material layer M1a, and the upper surface of the second connection part A1b is in contact with the lower surface of the second conductive material layer M1b.

The first conductive material layer M1a and the second conductive material layer M1b can be formed of the same material, for example, the same metal or metal oxide. For example, first conductive material layer M1a and the second conductive material layer M1b can be formed of a same material, on a same layer and during a same processing step.

The gate insulating layer 120 can be formed on the first active layer A1.

The gate insulating layer 120 can include, but is not limited thereto, a silicon nitride film SiNx or a silicon oxide film SiOx. The gate insulating layer 120 can have a single layer structure or a multilayer layer structure.

The first gate electrode G1 is formed on the gate insulating layer 120.

The first gate electrode G1 can overlap with the channel part A1n provided in the first active layer A1, and both ends of the first gate electrode G1 can coincide with both ends of the channel part A1n. For example, a length of the channel part A1n can be equal to a width of the first gate electrode G1.

The first gate electrode G1 includes an oxide semiconductor, and more particularly, includes a transparent conductive oxide semiconductor. For example, the first gate electrode G1 can include an oxide semiconductor material having low mobility characteristics.

According to an embodiment of the present disclosure, the gate electrode G1 can include at least one of an IGZO-based oxide semiconductor material, a GZO-based oxide semiconductor material, an IGO-based oxide semiconductor material, and a GZTO-based oxide semiconductor material, but embodiments are not limited thereto. When the first gate electrode G1 contains indium In and gallium Ga, the concentration (at %) of gallium Ga can be set higher than the concentration (at %) of indium In based on the number of atoms [Ga concentration>In concentration].

In this situation, the first gate electrode G1 can include a material different from than a material of the first active layer A1.

In order to improve the conductivity of the first gate electrode G1, the first gate electrode G1 can be formed by performing a conductorization process on a transparent oxide semiconductor.

The conductorization process can include a process of applying plasma to the oxide semiconductor in the process of etching the gate insulating layer to provide conductive properties, or a process of doping the oxide semiconductor with a dopant to provide conductive properties. The conductorization process is not limited thereto, and can include various processes according to the level of those skilled in the art.

Since the first gate electrode G1 includes a transparent conductive oxide semiconductor, the first thin film transistor TR1 according to an embodiment of present disclosure can improve reliability in a PBTIS (Positive Bias Temperature Illumination Stress) environment.

Since a high positive bias is applied to the thin film transistors provided in the buffer unit Buffer in the gate driver or the light emission control transistor EM provided in a pixel area, the reliability of the thin film transistor decreases over time due to stress and heat.

As the use time of the thin film transistor increases, the amount of charge trapped inside the first active layer A1 or at the interface between the first active layer A1 and the gate insulating layer 120 changes the threshold voltage Vth of the thin film transistor, and as a result, the reliability of the thin film transistor substrate can decrease.

According to an embodiment of the present disclosure, since the first gate electrode G1 includes a transparent conductive oxide semiconductor, light emitted can pass through the first gate electrode G1 and reach the first active layer A1. Accordingly, the amount of change in the threshold voltage of the thin film transistor can be reduced as charges trapped inside the first active layer A1 or at the interface between the first active layer A1 and the gate insulating layer 120 are de-trapped or released, and as a result, the reliability of the thin film transistor in the PBTIS environment can be improved.

The interlayer insulating layer 130 is formed on the first gate electrode G1.

The interlayer insulating film 130 insulates the first gate electrode G1 form the first source electrode S1, and further insulates the first gate electrode G1 from the first drain electrode D1. The interlayer insulating layer 130 can be formed of a single layer or a plurality of layers including an inorganic insulating material and/or an organic insulating material.

The interlayer insulating layer 130 is provided with a contact hole. Accordingly, a portion of the first conductive material layer M1a and the second conductive material layer M1b can be exposed by the contact hole.

The first source electrode S1 and the first drain electrode D1 can be formed on the interlayer insulating layer 130.

The first source electrode S1 is electrically connected to the first conductive material layer M1a through a contact hole provided in the interlayer insulating layer 130, and the first drain electrode D1 is electrically connected to the second conductive material layer M1b through a contact hole provided in the interlayer insulating layer 130.

FIG. 4C is a cross-sectional view of a node controller according to an embodiment of the present disclosure. In this situation, FIG. 4C corresponds to the cross section II-II′ of FIG. 4A.

The node controller NC includes a substrate 100, a buffer layer 110, a second active layer A2, a first conductive material layer M2a, a second conductive material layer M2b, a gate insulating layer 120, a second gate electrode G2, an interlayer insulating layer 130, a light shielding layer LS, a connection electrode CE, a second source electrode S2, and a second drain electrode D2. In this situation, the second active layer A2, the second gate electrode G2, the second source electrode S2, the second drain electrode D2, and the light shielding layer LS form the second thin film transistor TR2.

The second thin film transistor TR2 provided in the node controller NC can be formed through the same process as the process of forming the first thin film transistor TR1. Therefore, it is not necessary to add a separate mask or process to form a thin film transistor provided in the node controller NC.

The second active layer A2 can be formed on the buffer layer 110 by the same process as the first active layer A1 described above. Accordingly, the second active layer A2 can include a semiconductor material, for example, an oxide semiconductor material, in the same manner as the first active layer A1. In addition, the second active layer A2 includes a channel part A2n, a first connection part A2a, and a second connection part A2b, just like the first active layer A1.

The conductive material layers M2a and M2b can be formed by the same process as the conductive material layers M1a and M1b. Therefore, the conductive material layers M2a, M2b include the first conductive material layer M2a on the upper surface of the first connection part A2a, and the second conductive material layer M2b on the second connection part A2b.

The second gate electrode G2 can be formed by the same process as the first gate electrode G1. For example, the first gate electrode G1 and the second gate electrode G2 can be formed from a same material, on a same layer (e.g., gate insulating layer 120) and during the same processing step. Therefore, the second gate electrode G2 can overlap with the channel part A2n provided in the second active layer A2, and both ends of the second gate electrode G2 can coincide with both ends of the channel part A2n. In addition, the second gate electrode G2 includes an oxide semiconductor, and specifically, includes a transparent conductive oxide semiconductor. In addition, the second gate electrode G2 can be formed by performing a conductorization process on a transparent oxide semiconductor.

The light shielding layer LS is formed on the interlayer insulating layer 130. The light shielding layer LS can be formed of the same material in the same layer as the second source electrode S2 and the second drain electrode D2. The light shielding layer LS can include at least one of an aluminum-based metal such as aluminum Al or aluminum alloy, a silver-based metal such as silver Ag or silver alloy, a copper-based metal such as copper Cu or copper alloy, a molybdenum-based metal such as molybdenum Mo or molybdenum alloy, tantalum Ta, neodymium N, and titanium Ti.

The light shielding layer LS overlaps with the second gate electrode G2. Specifically, the light shielding layer LS can be formed in a form that entirely covers the second gate electrode G2, so that light does not penetrate onto the transparent second gate electrode G2. For example, the light shielding layer LS can prevent light from reaching the second gate electrode G2.

According to an embodiment of the present disclosure, the light shielding layer LS can be integrally formed with the second source electrode S2. Accordingly, the second source electrode S2 can extend over the second gate electrode G2 to also function as the light shielding layer LS. However, the present disclosure is not limited thereto, and the light shielding layer LS can be formed separately from the second source electrode S2 to overlap with the second gate electrode G2.

The connection electrode CE is connected to the first connection line CL1 provided in the buffer unit Buffer through a contact hole. In addition, the connection electrode CE can extend to form the second source electrode S2 and the light shielding layer LS. That is, the connection electrode CE, the second source electrode S2, and the light shielding layer LS can be integrally formed with each other as a same part.

The second source electrode S2 is connected to the first conductive material layer M2a through a contact hole provided in the gate insulating layer 120 and the interlayer insulating film 130, and the second drain electrode D2 is connected to the second conductive material layer M2b through a contact hole provided in the gate insulating layer 120 and the interlayer insulating film 130.

FIG. 5 is a graph of reliability of the first thin film transistor in a positive bias temperature stress (PBTS) environment and reliability in a positive bias temperature illumination stress (PBTIS) environment according to an embodiment of the present disclosure.

In FIG. 5, a square-shaped graph is a reliability graph of the first thin film transistor TR1 according to an embodiment of present disclosure in a PBTS environment, and a triangular-shaped graph is a reliability graph of the first thin film transistor TR1 according to an embodiment of present disclosure.

The PBTS reliability test can be performed by measuring the degree to which the threshold voltage of the thin film transistor changes by applying a stress voltage, especially a gate voltage, to the thin film transistor for a certain period of time at a constant positive bias and temperature. On the other hand, The PBTIS reliability test can be performed by measuring the degree to which the threshold voltage of the thin film transistor changes by applying a stress voltage, especially a gate voltage, to the thin film transistor for a certain period of time at a constant positive bias and temperature in the situation where additional illumination is irradiated onto the first thin film transistor TR1. In his situation, the reliability test was performed under a condition in which a positive bias is at 30 V and a temperature of 60 Celsius.

Reliability in the PBTS environment and the PBTIS environment can be said to be higher as the change in threshold voltage ΔVth over time (s) approaches 0V.

As can be seen from the square-shaped graph, it can be seen that the change amount ΔVth of the threshold voltage over time increases in the right-upward direction. This means that the first thin film transistor TR1 has poor reliability in a PBTS environment.

On the other hand, as can be seen from the graph illustrated as a triangle, it can be seen that the change amount ΔVth of the threshold voltage over time is close to 0V and is maintained at a constant level. This means that the reliability of the first thin film transistor TR1 in a PBTIS environment is improved.

Accordingly, it can be confirmed that reliability is improved when light is irradiated to the first thin film transistor TR1. In other words, there is no light shielding layer over the first thin film transistor TR1 and the first gate electrode G1 of the first thin film transistor TR1 is transparent, in order to allow additional light to fall onto the first active layer A1 which allows a build-up of charges to be released, and as a result, the reliability of the thin film transistor can be improved. In other words, the specific configuration allows just the right amount of light to hit the first active layer A1 which can release built-up charges that would otherwise remain trapped within the thin film transistor which would have caused the threshold voltage Vth of the thin film transistor to start to drift as the operating time increases.

As a result, since the first thin film transistor TR1 includes the first gate electrode G1 comprising a transparent conductive oxide semiconductor, the reliability of the first thin film transistor TR1 can be improved by having a proper amount of light be irradiated onto it while the display apparatus according to the embodiment of present disclosure is driven.

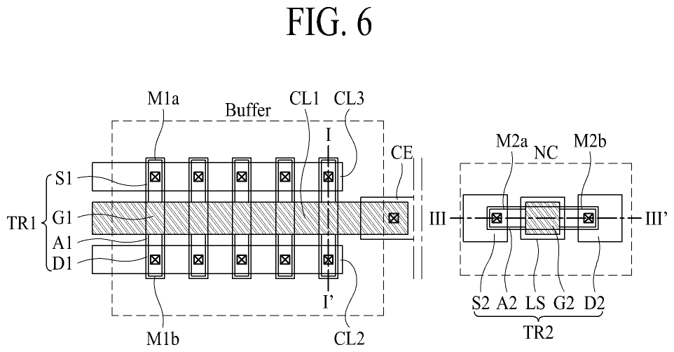

FIG. 6 is a plan view of a thin film transistor substrate according to another embodiment of the present disclosure.

As shown in FIG. 6, the thin film transistor substrate according to another embodiment of the present disclosure can include a buffer unit Buffer, a node controller NC, and a connection electrode CE.

Since the configurations of the buffer unit Buffer and the connection electrode CE are the same as those of the above-described embodiment, a repeated description thereof will be omitted.

The node controller NC includes a second thin film transistor TR2. In the aforementioned embodiment, a second thin film transistor TR2 connected to the connection electrode CE is shown, while FIG. 6 shows a second thin film transistor TR2 not connected to the connection electrode CE.

The second thin film transistor TR2 includes a second gate electrode G2, a second source electrode S2, a second drain electrode D2, a second active layer A2, and a light shielding layer LS.

In the aforementioned embodiment (e.g., FIGS. 4A and 4C), the connection electrode CE extends to the region over top of the second gate electrode G2 to be integrated with the second source electrode S2 and the light shielding layer LS. On the other hand, in the embodiment of FIG. 6, the connection electrode CE is not connected to the second source electrode S2 and the light shielding layer LS.

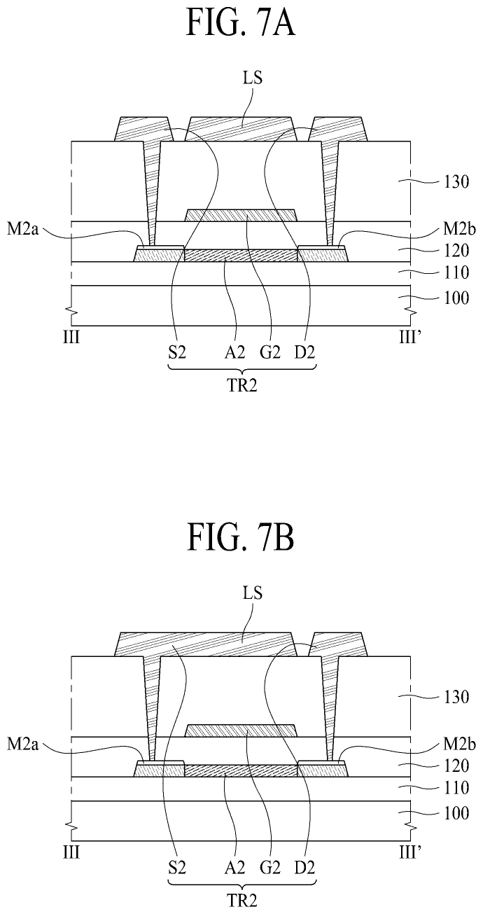

FIG. 7A is a cross-sectional view of a second thin film transistor according to another embodiment of the present disclosure. In this situation, FIG. 7A corresponds to a cross section III-III′ of FIG. 6.

The second thin film transistor TR2 according to FIG. 7A is the same as the second thin film transistor TR2 according to FIG. 4A except for that the light shielding layer LS and the second source electrode S2 are not connected to the connection electrode CE, and thus only different configurations will be mainly described.

The light shielding layer LS can be formed to be spaced apart from the second source electrode S2. Specifically, the light shielding layer LS can be formed on one side of the second source electrode S2, for example, on the left side to protect the second gate electrode G2.

The second thin film transistor TR2 according to another embodiment of present disclosure can be formed in the same process as the first thin film transistor TR1, and can prevent light from incident into the second active layer A2 by the light shielding layer LS.

FIG. 7B is a cross-sectional view of a second thin film transistor according to another embodiment of the present disclosure. In this situation, FIG. 7B corresponds to a cross section III-III′ of FIG. 6.

The embodiment in accordance with FIG. 7B is the same as the embodiment of FIG. 7A except for the configuration of the light shielding layer LS and thus only different configurations will be mainly described.

As shown in FIG. 7B, the second source electrode S2 can be integrally formed with the light shielding layer LS. For example, the second source electrode S2 cam have an extended portion that protrudes to overlap with the second gate electrode G2. Therefore, the second source electrode S2 extends to one side of the second source electrode S2 and, for example, to the right to overlap the second gate electrode G2. By being formed in this way, the second source electrode S2 can also serve as the light shielding layer LS (e.g., the second source electrode S2 can provide dual functions).

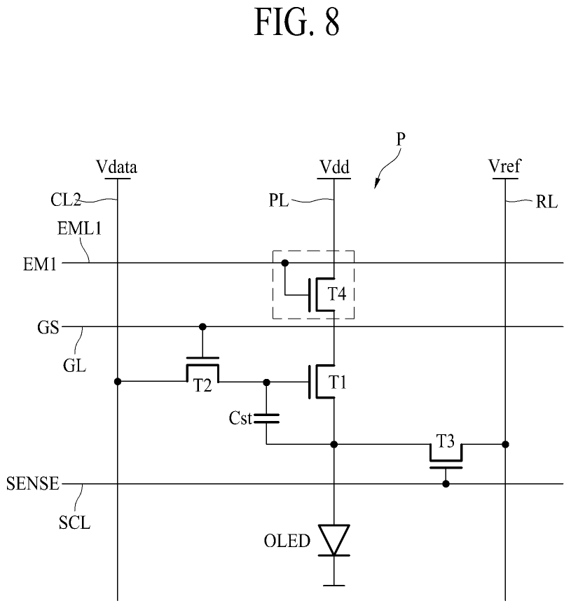

FIG. 8 is a circuit diagram of one pixel provided in a display area according to another embodiment of the present disclosure.

As shown in FIG. 8, the display apparatus according to an embodiment of the present disclosure includes a driving thin film transistor T1, first to third switching thin film transistors T2, T3, T4, and a capacitor Cst.

At least one of the driving thin film transistor and the first to third switching thin film transistors T1, T2, T3, and T4 can be formed of various thin film transistors described above.

The driving thin film transistor T1 is switched according to the data voltage Vdata supplied from the first switching thin film transistor T2 to generate data current from the driving voltage VDD supplied from the power line PL and supplies it to the organic light emitting diode OLED. The driving thin film transistor T1 can be formed of the second thin film transistor TR2 described above.

The first switching thin film transistor T2 is switched according to the gate signal GS supplied to the gate line GL and supplies the data voltage Vdata supplied from the data line DL to the driving thin film transistor T1. The first switching thin film transistor T2 can be formed of the second thin film transistor TR2 described above.

The second switching thin film transistor T3 supplies the current of the driving thin film transistor T1 to the reference line RL in response to the sensing control signal SENSE supplied from the scan line SCL. The reference voltage Vref is supplied to the reference line RL. The second switching thin film transistor T2 can be formed of the second thin film transistor TR2 described above.

The third switching thin film transistor T4 is switched according to the first light emission control signal EM1 supplied to the first light emission control line EML1 and supplies the driving voltage VDD supplied from the power line PL to the driving thin film transistor T1. The third switching thin film transistor T4 can be formed of the first thin film transistor TR1 described above.

Since the third switching thin film transistor T4 switched according to the light emission control signal EM is applied with a high constant Positive Bias, reliability is likely to decrease unless additional measures are taken (e.g., such as irradiated just the right amount of light to the active layer of the thin film transistor T4 while it is in operation). Therefore, when the third switching thin film transistor T4 is composed of the first thin film transistor TR1, just the right amount of light can be irradiated onto the active layer in order to prevent the build of an undesirable amount charges, the threshold voltage Vth can be kept more stable and reliability can be improved.

As such, according to an embodiment of present disclosure, the driving thin film transistor, the first switching thin film transistor, and the second switching thin film transistor T1, T2, and T3 can be made of the second thin film transistor TR2, and the third switching thin film transistor T4 can be made of the first thin film transistor TR1. Accordingly, the driving thin film transistor, the first switching thin film transistor, and the second switching thin film transistor T1, T2, and T3 can be formed in the same process as the third switching thin film transistor T4.

The capacitor Cst serves to maintain the data voltage supplied to the driving thin film transistor T1 for one frame, and is provided between the gate electrode and the source electrode of the driving thin film transistor T1.

The organic light emitting diode OLED emits predetermined light according to a data current supplied from the driving thin film transistor T1.

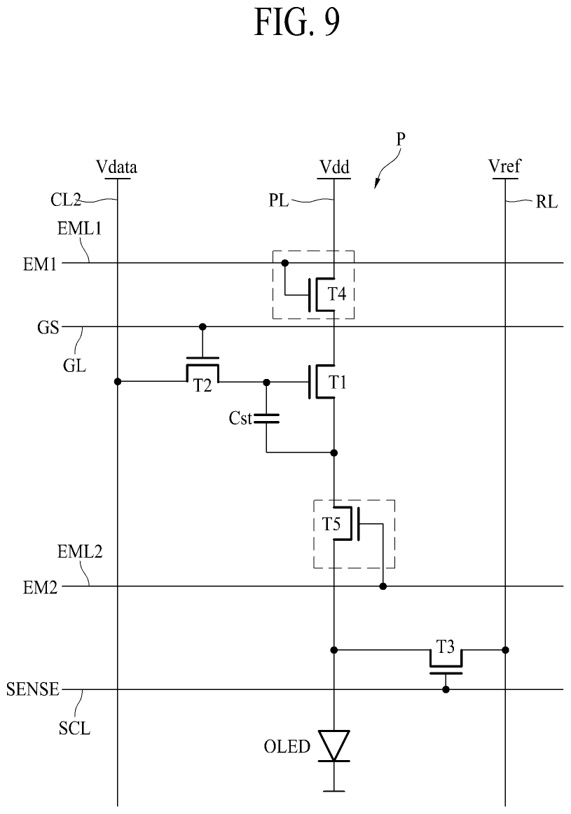

FIG. 9 is a circuit diagram of one pixel provided in a display area according to another embodiment of the present disclosure.

As shown in FIG. 9, a display apparatus according to another embodiment of the present disclosure includes a driving thin film transistor T1, first to fourth switching thin film transistors T2, T3, T4, T5, and a capacitor Cst. In this situation, the configuration of the driving thin film transistor T1, the first to third switching thin film transistors T2, T3, T4, and the capacitor Cst is the same as the embodiment shown in FIG. 8, so the only different configurations will be mainly described.

The fourth switching thin film transistor T5 is switched according to the second light emission control signal EM2 supplied to the second light emission control line EML2 and supplies the driving voltage VDD supplied from the power line PL to the organic light emitting diode OLED.

According to another embodiment of the present disclosure, the fourth switching thin film transistor T5 for controlling light emission can be composed of the first thin film transistor TR1 described above.

Since the fourth switching thin film transistor T5 switched according to the second light emission control signal EM2 is applied with a high constant Positive Bias, reliability is likely to decrease. According to an embodiment of the present disclosure, reliability can be improved when the fourth switching thin film transistor T5 is formed of the first thin film transistor TR1.

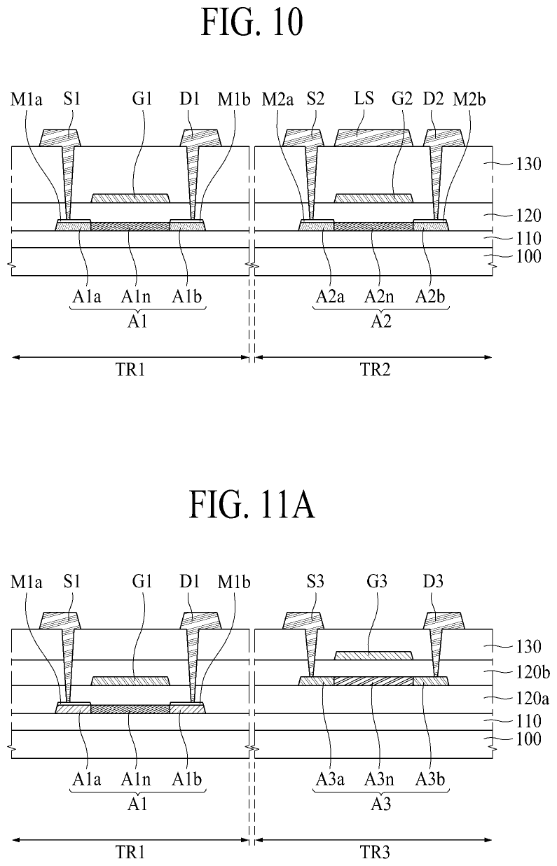

FIG. 10 is a cross-sectional view of a thin film transistor substrate according to another embodiment of the present disclosure.

As shown in FIG. 10, a thin film transistor substrate according to another embodiment of the present disclosure includes a first thin film transistor TR1 and a second thin film transistor TR2. For example, the two different types of transistors can be formed on the same a layer, from the same materials and during a same manufacturing process.

The first thin film transistor TR1 can include any one of the multiple thin film transistors in the pixel area, for example, the third switching thin film transistor T4 or the fourth switching thin film transistor T5 of FIG. 9.

The second thin film transistor TR2 can include any one of a plurality of thin film transistors provided in the pixel area, for example, the driving thin film transistor, the first switching thin film transistor, or the second switching thin film transistor T1, T2, and T3 of FIG. 9.

In this way, the reliability of the thin film transistor with relatively high positive bias, such as the third switching thin film transistor and the fourth switching thin film transistor T4, T5 can be improved, and the reliability of the thin film transistor with a relatively low Positive Bias, such as the driving thin film transistor, the first thin film transistor, and the second thin film transistor, T2, is not reduced.

Since the first thin film transistor TR1 is the same as FIG. 4B, and the second thin film transistor TR2 is the same as FIG. 7A, a repeated description will be omitted.

According to an embodiment of the present disclosure, since the second thin film transistor TR2 includes the light shielding layer LS, the emitted light does not pass through the second gate electrode G2 and does not reach the second active layer A2. That is, the reliability of the thin film transistor including the second thin film transistor TR2, for example, the driving thin film transistor, the first switching thin film transistor, and the second switching thin film transistor T1, T2, and T3 does not decrease.

Meanwhile, the second thin film transistor TR2 can be formed in the same manner as in FIG. 7B described above. That is, the second source electrode S2 can be integrally formed with the light shielding layer LS.

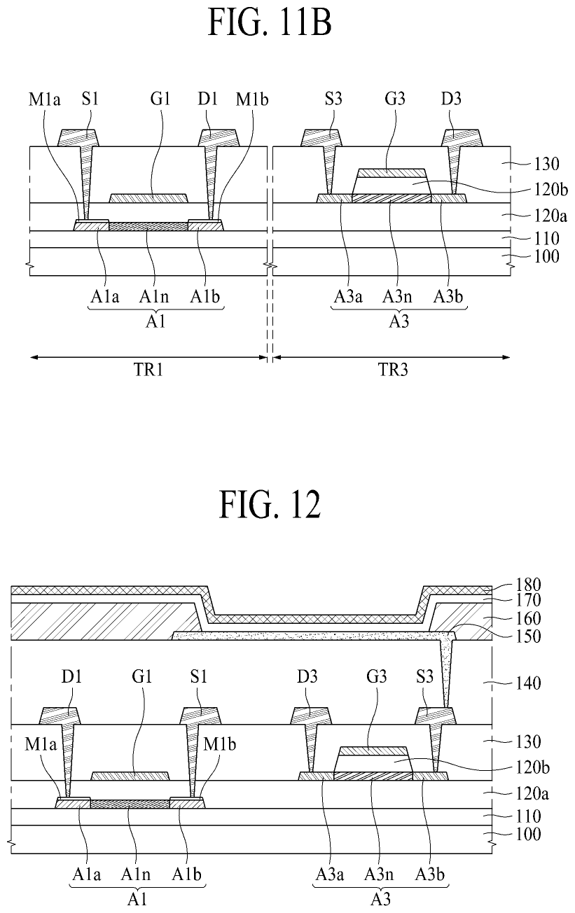

FIG. 11A is a cross-sectional view of a thin film transistor substrate according to another embodiment of the present disclosure.

As shown in FIG. 11A, a thin film transistor substrate according to another embodiment of the present disclosure includes a first thin film transistor TR1 and a third thin film transistor TR3.

The first thin film transistor TR1 can include any one of the multiple thin film transistors in the pixel area, for example, the third switching thin film transistor T4 or the fourth switching thin film transistor T5 of FIG. 9.

The first thin film transistor TR1 is the same as the first thin film transistor TR1 of FIG. 10, except that a first gate insulating layer 120a is provided under the first gate electrode G1, a second gate insulating layer 120b is provided on the first gate electrode G1, and an interlayer insulating layer 130 is provided on the second gate insulating layer 120b, and thus a repeated description thereof will be omitted. For example, the active layers A1 and A3 can be disposed on different layers.

The first gate insulating layer 120a can be the same as the gate insulating layer 120 described above, and the second gate insulating layer 120b can include a silicon nitride film SiNx or a silicon oxide film SiOx, but is not limited thereto. The second gate insulating layer 120b can have a single layer structure or a multilayer layer structure.

The third thin film transistor TR3 can include any one of a plurality of thin film transistors provided in the pixel area, for example, the driving thin film transistor, the first switching thin film transistor, or the second switching thin film transistor T1, T2, and T3 of FIG. 9.

The third thin film transistor TR3 can include a third active layer A3, a third gate electrode G3, a third source electrode S3, and a third drain electrode D3.

The third active layer A3 is formed on the first gate insulating layer 120a.

The third active layer A3 includes a channel part A3n, a first connection part A3a, and a second connection part A3b. The first connection part A3a can be connected to one side of the channel part A3n, and the third connection part A3b can be connected to another side of the channel part A3n. The channel part A3n is made of a semiconductor material and can overlap the third gate electrode G3 to be protected by the third gate electrode G3. The first connection part A3a and the second connection part A3b can have conductive properties by a conductorization process conducting the third active layer A3 using the third gate electrode G3 provided in the third thin film transistor TR3 as a mask. In this situation, according to an embodiment of the present disclosure, the conductorization process can be performed through, for example, an ion doping process.

The first connection part A3a and the second connection part A3b may not overlap with the third gate electrode G3. The first connection part A3a and the second connection part A3b have excellent conductivity compared to the channel part A3n, and each can serve as a wiring or source/drain electrode.

The third active layer A3 can include an oxide semiconductor, and for example, the third active layer A3 can include an oxide semiconductor material having low mobility characteristics.

According to an embodiment of the present disclosure, the third active layer A3 can include at least one of an IGZO-based oxide semiconductor material, a GZO-based oxide semiconductor material, an IGO-based oxide semiconductor material, and a GZTO-based oxide semiconductor material. When the first gate electrode G1 contains indium In and gallium Ga, the concentration (at %) of gallium Ga can be set higher than the concentration (at %) of indium In based on the number of atoms [Ga concentration>In concentration].

The third active layer A3 can include the same material in the same layer as the first gate electrode G1 of the first thin film transistor TR1.

In general, since the third active layer A3 is made of a semiconductor material, and the first gate electrode G1 is made of a metal material, it is difficult for the third active layer A3 and the first gate electrode G1 to be formed on the same layer.

On the other hand, in one embodiment of present disclosure, since the first gate electrode G1 is formed by the conductorization on the oxide semiconductor material constituting the third active layer A3, the third active layer A3 and the first gate electrode G1 can be formed on the same layer. Accordingly, the on current characteristics of the first thin film transistor TR1 can be improved by reducing the distance between the first active layer A1 and the first gate electrode G1.

Meanwhile, according to an embodiment of the present disclosure, the thickness of the second gate insulating layer 120b can be greater than the thickness of the first gate insulating layer 120a. For example, when the third thin film transistor TR3 is composed of the driving thin film transistor T1, the thickness of the second gate insulating layer 120b can be increased to increase the distance between the third active layer A3 and the third gate electrode G3.

The third gate electrode G3 is formed on the second gate insulating layer 120b.

The third gate electrode G3 can include at least one of an aluminum-based metal such as aluminum Al, a silver-based metal such as silver Ag, a copper-based metal such as copper Cu, a molybdenum-based metal such as molybdenum Mo, tantalum Ta, neodymium N, and titanium Ti. The third gate electrode G3 can have a multilayer structure including at least two different conductor layers.

The interlayer insulating film 130 is formed on the third gate electrode G3, and the third source electrode S3 and the third drain electrode D3 are formed on the interlayer insulating film 130. At this time, each of the source electrode S3 and the third drain electrode D3 can be electrically connected to the first connection part A3a or the second connection part A3b through a contact hole provided on the interlayer insulating film 130.

FIG. 11B is a cross-sectional view of a thin film transistor substrate according to another embodiment of the present disclosure.

The embodiment of FIG. 11B is the same as the embodiment of FIG. 11A except that the structure of the second gate insulating layer 120b is changed (e.g., it is only provided under the third gate electrode G3), and thus only different configurations will be mainly described.

As shown in FIG. 11B, the second gate insulating layer 120b can have an etch structure. Therefore, the second gate insulating layer 120b may not be formed over the entire substrate 100, but can be provided only in some areas of the third active layer A3 of the third thin film transistor TR3.

In the process of forming the second gate insulating layer 120b in an etch structure, a dry etch process can be performed, and in this situation, a portion of the third active layer A3 can be conductorized by plasma treatment to provide conductive properties. In this situation, a partial region of the third active layer A3 can be a first connection part A3a and a second connection part A3b of the third active layer A3.

According to an embodiment of the present disclosure, the first gate electrode G1 provided in the first thin film transistor TR1 can also be conductorized by the conductorization process by the plasma treatment to have conductive properties. Since the first gate electrode G1 is conductorized by the conductorization process by the plasma treatment, the plasma does not reach the channel part A1n of the first active layer A1, and thus device characteristics of the first thin film transistor TR1 are not be degraded.

According to an embodiment of the present disclosure, the second gate insulating layer 120b can overlap with the channel part A3n of the third active layer A3, but may not overlap with the first connection part A3a and the second connection part A3b. In addition, both ends of the second gate insulating layer 120b can coincide with both ends of the third gate electrode G3, respectively.

Meanwhile, the structure of the third thin film transistor TR3 shown in FIGS. 11A and 11B can be applied to the node controller NC of FIGS. 4A and 6. That is, the second thin film transistor TR2 provided in the node controller NC of FIGS. 4A and 6 can be replaced with the third thin film transistor TR3 shown in FIGS. 11A and 11B.

FIG. 12 is a cross-sectional view of a display apparatus including a thin film transistor substrate according to an embodiment of the present disclosure.

As shown in FIG. 12, the display apparatus according to the embodiment of present disclosure includes a substrate 100, a buffer layer 110, a first active layer A1, a first gate insulating layer 120a, a first gate electrode G1, a third active layer A3, a second gate insulating layer 120b, a third gate electrode G3, an interlayer insulating layer 130, a first source electrode S1, a first drain electrode D1, a third source electrode S3, a third drain electrode D3, a planarization layer 140, a first electrode 150, a bank layer 160, a light emitting layer 170 and a second electrode 180.

Although the substrate 100, buffer layer 110, first active layer A1, first gate insulating layer 120a, first gate electrode G1, third active layer A3, second gate insulating layer 120b, third gate electrode G3, interlayer insulating layer 130, first source electrode S1, first drain electrode D1, third source electrode S3, and third drain electrode D3 is illustrated in the same structure as FIG. 11B, but it is not necessarily limited thereto and can be formed in a structure as illustrated in FIG. 11A. On the other hand, the structure of the second active layer A2, the second gate electrode G2, the second source electrode S2, and the second drain electrode D2 of FIG. 10 can be applied instead of the structure of the third active layer A3, the third gate electrode G3, and the third drain electrode D3 of FIGS. 11A and 11B.

The planarization layer 140 is provided on the first source electrode S1, the first drain electrode D1, the third source electrode S3, and the third drain electrode D3. Since a contact hole is provided in the planarization layer 140, the third source electrode S3 is exposed by the contact hole. However, in some situations, the third drain electrode D3 can be exposed by the contact hole

The first electrode 150 is formed on the planarization layer 140, and is connected to the third source electrode S3 through the contact hole provided in the planarization layer 140. The first electrode 150 can function as an anode.

The bank layer 160 is provided to cover an edge of the first electrode 150 to define a light emitting area. Accordingly, the upper surface area of the first electrode 150 exposed without being covered by the bank layer 160 becomes a light emitting area.

The light emitting layer 170 is provided on the first electrode 150. the light emitting layer 170 can include a red, green, and blue emission layer patterned for each pixel, or can include a white emission layer connected to all pixels. When the light emitting layer 170 is made of a white light emitting layer, the light emitting layer 170 can include, for example, a first stack including a blue light emitting layer, a second stack including a yellow green light emitting layer, and a charge generation layer provided between the first stack and the second stack.

The second electrode 180 is provided on the light emitting layer 170. The second electrode 180 can function as a cathode.

Also, an encapsulation layer for preventing moisture or oxygen from penetrating can be additionally formed on the second electrode 180.

Accordingly, the present disclosure can have the following advantages.

According to an embodiment of the present disclosure, the thin film transistor Tu, Td provided in the buffer unit of the gate driver or the thin film transistor EM provided in a pixel region in which a high positive bias is applied is the first thin film transistor and the gate electrode provided in the first thin film transistor is made with a transparent conductive oxide semiconductor, thereby improving the reliability of thin film transistor in the positive bias temperature illumination (PBTIS) environment.

According to one embodiment of the present disclosure, another plurality of thin film transistors having a relatively low positive bias are made of the second thin film transistor, and the second thin film transistor further includes the light shielding layer. the first thin film transistor and the second film transistor can be selectively used according to the applied positive bias.

According to an embodiment of the present disclosure, since the first thin film transistor and the second thin film transistor can be formed in the same process, a separate process for forming the second thin film transistor is not required, and thus an additional cost problem does not occur.

According to one embodiment of the present disclosure, another plurality of thin film transistors with a relatively low positive bias are made of a third thin film transistor, and the third gate electrode of the third film transistor may not include a transparent conductive oxide semiconductor material. In this situation, since the first gate electrode of the first thin film transistor and the third active layer of the third thin film transistor can be patterned in the same process, a thickness of insulating layer disposed between the first active layer and the first gate electrode of the first thin film transistor may not be formed thicker. Accordingly, the on current characteristics of the first thin film transistor can be improved.

According to an embodiment of the present disclosure, since the first gate electrode of the first thin film transistor and the third active layer of the third thin film transistor can be applied in the same process, a thickness of second gate insulating layer disposed between the third active layer and the third gate electrode can be selectively adjusted. Accordingly, the S-factor of the third thin film transistor can be easily adjusted.

It will be apparent to those skilled in the art that various substitutions, modifications, and variations are possible within the scope of the present disclosure without departing from the spirit and scope of the present disclosure. Therefore, the scope of the present disclosure is represented by the following claims, and all changes or modifications derived from the meaning, range and equivalent concept of the claims should be interpreted as being included in the scope of the present disclosure.

What is claimed is:

1. A thin film transistor substrate comprising:
a first thin film transistor disposed on a base substrate, the first thin film transistor including a first source electrode, a first drain electrode, a first active layer and a first gate electrode,
wherein the first gate electrode is disposed on the first active layer and includes a transparent conductive oxide semiconductor material.

2. The thin film transistor substrate according to claim 1, wherein the first active layer includes an oxide semiconductor material different from the transparent oxide semiconductor material of the first gate electrode.

3. The thin film transistor substrate according to claim 1, wherein the first gate electrode includes at least one of a GZO(GaZnO)-based oxide semiconductor material, and a GZTO(GaZnSnO)-based oxide semiconductor material.

4. The thin film transistor substrate according to claim 1, wherein the first gate electrode includes at least one of a IGZO(InGaZnO)-based oxide semiconductor material and a IGO(InGaO)-based oxide semiconductor material, and
wherein a concentration of the gallium (Ga) is higher than a concentration of the indium (In) based on a number of atoms.

5. The thin film transistor substrate according to claim 1, wherein the first active layer includes at least one of a IZO(InZnO)-based oxide semiconductor material, a ITZO(InSnZnO)-based oxide semiconductor material, a FIZO(FeInZnO)-based oxide semiconductor material, a ZnO-based oxide semiconductor material, a SIZO(SiInZnO)-based oxide semiconductor material, and a ZnON-based oxide semiconductor material.

6. The thin film transistor substrate according to claim 1, wherein the first active layer includes at least one of a IGZO(InGaZnO)-based oxide semiconductor material and a IGZTO(InGaZnSnO)-based oxide semiconductor material, and
wherein a concentration of the indium (In) is higher than a concentration of the gallium (Ga) based on a number of atoms.

7. The thin film transistor substrate according to claim 1, further comprising:
a first conductive material layer disposed on a first side of the first active layer of the first thin film transistor, and
a second conductive material layer disposed on a second side of the first active layer of the first thin film transistor,
wherein the first conductive material layer is electrically connected to the first source electrode, and the second conductive material layer is electrically connected to the first drain electrode.

8. The thin film transistor substrate according to claim 1, further comprising:
a gate driver disposed on the substrate and including a plurality of thin film transistors connected in parallel with each other,
wherein the plurality of thin film transistors include the first thin film transistor.

9. The thin film transistor substrate according to claim 8, wherein the gate driver includes a shift register, and the shift register includes a pull-up transistor configured to output a gate on signal and a pull-down transistor configured to output a gate-off signal, and
wherein the pull-up transistor or the pull-down transistor includes the first thin film transistor.

10. The thin film transistor substrate according to claim 1, further comprising:
a second thin film transistor including a second source electrode, a second drain electrode, a second active layer, and a second gate electrode; and
a light shielding layer disposed on the second thin film transistor,
wherein the second gate electrode is disposed on the second active layer and includes a transparent conductive oxide semiconductor material, and
wherein the light shielding layer overlaps with the second gate electrode.

11. The thin film transistor substrate according to claim 10, wherein one end of the second gate electrode is aligned with one end of a channel part of the second active layer.

12. The thin film transistor substrate according to claim 10, wherein the light shielding layer is disposed on a same layer as the second source electrode and the second drain electrode.

13. The thin film transistor substrate according to claim 10, wherein the second gate electrode of the second thin film transistor includes a same material as the first gate electrode of the first thin film transistor, and the second gate electrode of the second thin film transistor is disposed on a same layer as the first gate electrode of the first thin film transistor.

14. The thin film transistor substrate according to claim 10, further comprising:
a first conductive material layer disposed on a first side of the second active layer of the second thin film transistor; and
a second conductive material layer disposed on a second side of the second active layer of the second thin film transistor.

15. The thin film transistor substrate according to claim 10, further comprising:
a gate driver disposed on the substrate, the gate driver including a shift register, wherein the shift register includes a buffer unit and a node controller,
wherein the buffer unit includes the first thin film transistor, and
wherein the node controller includes the second thin film transistor.

16. The thin film transistor substrate according to claim 15, further comprising:
a connection electrode connecting the first thin film transistor of the buffer unit with the second thin film transistor of the node controller,
wherein the connection electrode and the light shielding layer are provided as one body.

17. The thin film transistor substrate according to claim 1, further comprising:
a third thin film transistor including a third source electrode, a third drain electrode, a third active layer and a third gate electrode,
wherein the third active layer includes a same material as the first gate electrode of the first thin film transistor, and
wherein the third gate electrode is disposed on the third active layer.

18. The thin film transistor substrate according to claim 17, wherein the third active layer includes an oxide semiconductor material different from an oxide semiconductor material of the first active layer.

19. The thin film transistor substrate according to claim 18, wherein a mobility of the first active layer is greater than a mobility of the second active layer.

20. The thin film transistor substrate according to claim 17, wherein the third active layer includes a channel part, a first connection part disposed on a first side of the channel part and a second connection part disposed on a second side of channel part, and
wherein the first gate electrode is formed of a same material and a same process as the first connection part and the second connection part of the third active layer.

21. The thin film transistor substrate according to claim 20, further comprising:
a second gate insulating layer disposed on the first gate electrode and the third active layer,
wherein the first gate electrode, the first connection part of the third active layer and the second connection part of the third active layer include a same type of dopant.

22. The thin film transistor substrate according to claim 20, further comprising:
a second gate insulating layer disposed on the third active layer without overlapping with the first gate electrode,
wherein the first gate electrode, the first connection part of the third active layer and the second connection part of the third active layer are plasma treated.

23. The thin film transistor substrate according to claim 17, further comprising:
a gate insulating layer disposed on the first active layer of the first thin film transistor,
wherein the first gate electrode of the first thin film transistor and the third active layer of the third thin film transistor are disposed on a same layer on the gate insulating layer.

24. The thin film transistor substrate according to claim 17, further comprising:
a pixel region defined on the substrate,
wherein the pixel region includes a plurality of thin film transistors,
the plurality of thin film transistors includes a light emitting control transistor and a driving thin film transistor,
the first thin film transistor includes the light emitting control transistor, and
the third film transistor includes the driving thin film transistor.

25. A display apparatus comprising:
a plurality of subpixels; and
the thin film transistor substrate according to claim 1.

26. A thin film transistor substrate comprising:
a first oxide semiconductor transistor disposed on a base substrate, the first oxide semiconductor transistor including a first source electrode, a first drain electrode, a first active layer including an oxide semiconductor material, and a first gate electrode;
a second oxide semiconductor transistor disposed on the base substrate, the second oxide semiconductor transistor including a second source electrode, a second drain electrode, a second active layer including an oxide semiconductor material, and a second gate electrode; and
a light shielding layer disposed over the second gate electrode without overlapping with the first gate electrode,
wherein the first gate electrode is transparent and configured to allow light to be irradiated onto the first active layer.

27. The thin film transistor substrate according to claim 26, wherein the first active layer and the second active layer are disposed on a same layer.

28. The thin film transistor substrate according to claim 26, wherein the first oxide semiconductor transistor is configured to receive a first positive bias,
wherein the second oxide semiconductor transistor is configured to receive a second positive bias, and
wherein the first positive bias is higher than the second positive bias.
